(19) United States
(12) Patent Application Publication
(10) Pub. No.: US 2003/0127724 A1
(43) Pub. Date: Jul. 10, 2003

(54) Double side connected type semiconductor apparatus

(75) Inventor: Naoji Senba, Kanagawa (JP)

Correspondence Address: SUGHRUE MION, PLLC, 2100 PENNSYLVANIA AVENUE, N.W., WASHINGTON, DC, 20037, US

(73) Assignee: NEC ELECTRONICS CORPORATION

(21) Appl. No.: 10/327,044

(22) Filed: Dec. 24, 2002

(30) Foreign Application Priority Data
Dec. 26, 2001 (JP) 394441/2001

(51) Int. Cl. H01L 23/02; H01L 23/48

(52) U.S. Cl. 257/698; 257/685; 257/686; 257/692

(57) ABSTRACT

There is disclosed a double side connected type semiconductor apparatus comprising pads for external connection on both sides, semiconductor devices formed on both sides of a semiconductor substrate, and conductor portions which perform electrical connection between the pads and between the pads and the semiconductor devices, wherein the semiconductor devices are formed on both the sides of the semiconductor substrate in accordance with a selective impurity diffusing method; the conductor portions are formed in such a manner that impurities are diffused only in required parts on both the sides of the semiconductor substrate in accordance with the selective impurity diffusing method, so that a resistivity of the diffused part of the semiconductor substrate lowers, which enables electric conduction; and the conductor portions are electrically insulated from the semiconductor devices by isolations.

### BACKGROUND OF THE INVENTION

1. Field of the Invention

The present invention relates to a double side connected type semiconductor apparatus, and more particularly relates to a double side connected type semiconductor apparatus formed by use of a semiconductor diffusion process.

2. Description of the Related Art

A double side connected type semiconductor apparatus in the prior art has a constitution in which through vias are formed at pad positions of a semiconductor device in accordance with a method such as an etching, electrolyzation (photoexcitation) in light or liquid, or plasma etching method, so as to electrically and mechanically connect two sides of a chip, as disclosed on pages 160 to 164 in the May 2000 issue of NIKKEI MICRODEVICES. Hereinafter, detailed description will be given using FIG. 13. Through vias 52 are formed at pad positions of a chip 51 in accordance with a method such as the etching, electrolyzation (photoexcitation) in light or liquid, or plasma etching method [FIG. 13A]. Next, oxide films 53 are formed on inner faces of the through vias 52, in accordance with a method such as a CVD method or thermal oxidation method, thereby securing electric insulation from the chip 51 [FIG. 13B]. Conductive electrode materials 54 are filled in the through vias 52 in which the oxide films 53 are formed, so as to form conductors for vertical connection of pads [FIG. 13C]. Finally, for multistage connection, a vertical position adjustment is applied to the through vias 52 of the chips 51 in which the conductive electrode materials 54 are formed, and then a desired number of stages are connected using conductive materials 56 in accordance with methods such as a reflow method and heat treatment method, whereby a multistage connected type semiconductor apparatus is formed. After that, the multistage connected type semiconductor apparatus is mounted on a mother board 55 also using the conductive materials 56 in accordance with methods such as the reflow method and heat treatment method, thus having such constitution. In some cases, metal bumps 57 may be formed to be fixed to the mother board [FIG. 13D].

In the prior art, the through vias are formed in order to have vertical conduction at the pad positions of the semiconductor device, in accordance with a method such as the etching or electrolyzation (photoexcitation) method in light or liquid. To put this into practice, it is necessary to have a through via forming process technology that departs from a conventional semiconductor diffusion process, along with proportionate equipment investment. Further, because the through via forming process is performed after forming the semiconductor device, it is necessary to protect the semiconductor device by some kind of means in the through via forming process, and have a process of eliminating the protection means after completion, which increases costs because of the mixed different kinds of processes and increased total number of processes. In addition, advanced techniques are required for each process. Furthermore, because the electrode materials having properties different from that of a semiconductor substrate are used for the vertical conduction means, cracks, chips or the like are caused in through via parts due to the difference in thermal expansion, thermal conduction or the like, and moreover a leak current is increased and the electrode materials cause short circuit defects in association with the semiconductor devices, which might lead to deterioration in quality. In addition, owing to a bare chip assembly, mounting density is improved, but the semiconductor device is formed on only one side of the semiconductor substrate. Therefore, such problems are presented that the mounting density is not dramatically improved as compared with the conventional cases.

### SUMMARY OF THE INVENTION

The present invention is directed to a double side connected type semiconductor apparatus comprising pads for external connection on both sides, semiconductor devices formed on both sides of a semiconductor substrate, and conductor portions which perform electrical connection between the pads and between the pads and the semiconductor devices, wherein the semiconductor devices are formed on both the sides of the semiconductor substrate in accordance with a selective impurity diffusing method; the conductor portions are formed in such a manner that impurities are diffused only in required parts on both the sides of the semiconductor substrate in accordance with the selective impurity diffusing method, so that a resistivity of the diffused part of the semiconductor substrate lowers, which enables electric conduction; and the conductor portions are electrically insulated from the semiconductor devices by isolations.

### BRIEF DESCRIPTION OF THE DRAWINGS

The above-mentioned and other objects, features and advantages of this invention will become more apparent by reference to the following detailed description of the invention taken in conjunction with the accompanying drawings, wherein:

FIG. 1 is a schematic sectional view of a double side connected type semiconductor apparatus in a first embodiment of the present invention;

FIGS. 2A to 2E are schematic sectional views for describing an outline of a manufacturing process for the double side connected type semiconductor apparatus in the first embodiment;

FIGS. 3F to 3J are schematic sectional views for describing an outline of the manufacturing process for the double side connected type semiconductor apparatus in the first embodiment following FIG. 2;

FIGS. 4K to 4O are schematic sectional views for describing an outline of the manufacturing process for the double side connected type semiconductor apparatus in the first embodiment following FIG. 3;

FIGS. 5P to 5R are schematic sectional views for describing an outline of the manufacturing process for the double side connected type semiconductor apparatus in the first embodiment following FIG. 4;

FIG. 6 is a schematic sectional view of a multistage laminated type semiconductor apparatus in a second embodiment of the present invention;

FIG. 7 is a schematic fragmentary sectional view showing a state where the double side connected type semiconductor apparatus in a third embodiment of the present invention is mounted on an electronic component;

FIG. 8 is a schematic fragmentary sectional view showing a state where the multistage laminated type semiconductor apparatus in a fourth embodiment of the present invention is mounted on an electronic component;

FIG. 9 is a schematic fragmentary sectional view showing a state where the double side connected type semiconductor apparatus in a fifth embodiment of the present invention is resin-encapsulated;

FIG. 10 is a schematic fragmentary sectional view showing a state where the multistage laminated type semiconductor apparatus in a sixth embodiment of the present invention is resin-encapsulated;

FIG. 11 is a schematic fragmentary sectional view showing a state where the resin-encapsulated double side connected type semiconductor apparatus in a seventh embodiment of the present invention is mounted on an electronic component;

FIG. 12 is a schematic fragmentary sectional view showing a state where the resin-encapsulated multistage laminated type semiconductor apparatus in an eighth embodiment of the present invention is mounted on an electronic component; and

FIGS. 13A to 13D are schematic sectional views for describing an outline of a manufacturing process for the double side connected type semiconductor apparatus in the prior art.

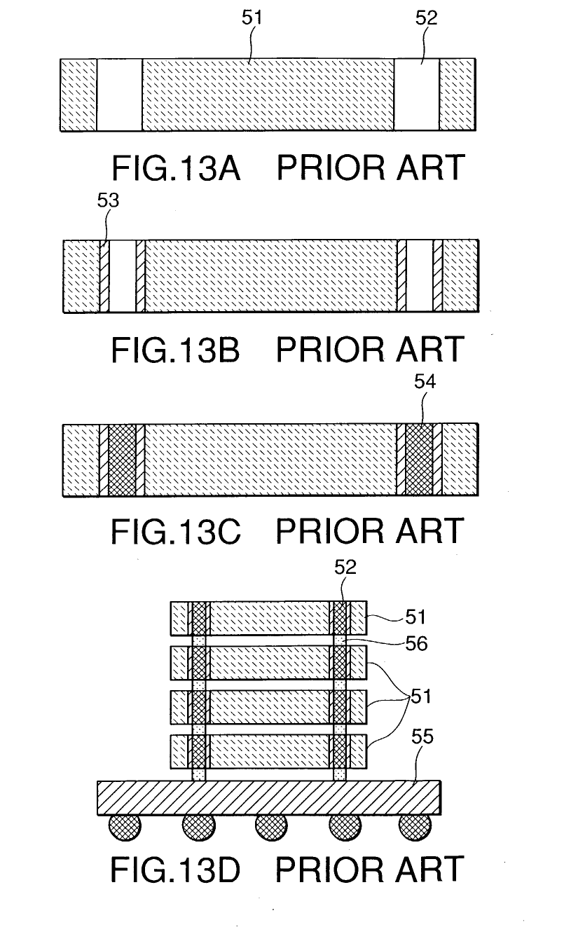

### DETAILED DESCRIPTION OF THE PREFERRED EMBODIMENTS

A double side connected type semiconductor apparatus of the present invention has a constitution in which semiconductor devices are formed on both sides of a semiconductor substrate using a conventional semiconductor diffusion process, and also has a constitution in which electric conducting parts are formed by diffusing impurities in required parts of pad units of the semiconductor devices on both sides and reducing the resistivity of the semiconductor substrate, also by use of the conventional semiconductor diffusion process, as means for multistage-connecting semiconductor chips having the double side semiconductor device constitution. Further, a multistage laminated type semiconductor apparatus of the present invention has a constitution in which the double side connected type semiconductor apparatuses are accumulated and interconnected.

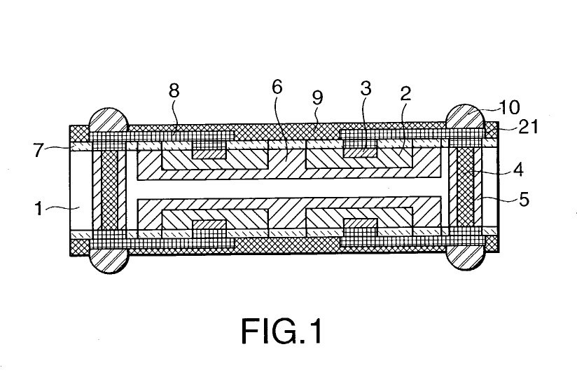

Hereinafter, embodiments of the present invention will be described in detail with reference to the drawings. FIG. 1 is a schematic sectional view of the double side connected type semiconductor apparatus in a first embodiment of the present invention.

In the double side connected type semiconductor apparatus in the first embodiment, ICs of the semiconductor devices including first bases 2 and second bases 3 are formed on second isolations 6 formed on both sides of a semiconductor substrate 1, and conducting units 4 for electrically conducting both sides of the semiconductor substrate are provided outside a semiconductor device forming area, and further first isolations 5 are formed around the conducting units 4 to electrically separate the conducting units 4 from the semiconductor devices. Pads of the semiconductor devices and the conducting units 4 are connected by conductors 8 formed on oxide films 7, and bumps 10 are formed on the respective pads of the conducting units 4 via barrier metals 21, and moreover the entire surfaces of both sides of the semiconductor substrate except for the parts where the bumps 10 are formed are protected by protection films 9.

The semiconductor devices are formed on both sides of the semiconductor substrate 1 in accordance with a selective impurity diffusing method, and the conducting units 4 are formed in such a way that impurities are diffused only in required parts on both sides of the semiconductor substrate 1 in accordance with the selective impurity diffusing method, and electric conduction becomes possible by the resistivity decrease of the semiconductor substrate 1 in the diffused parts.

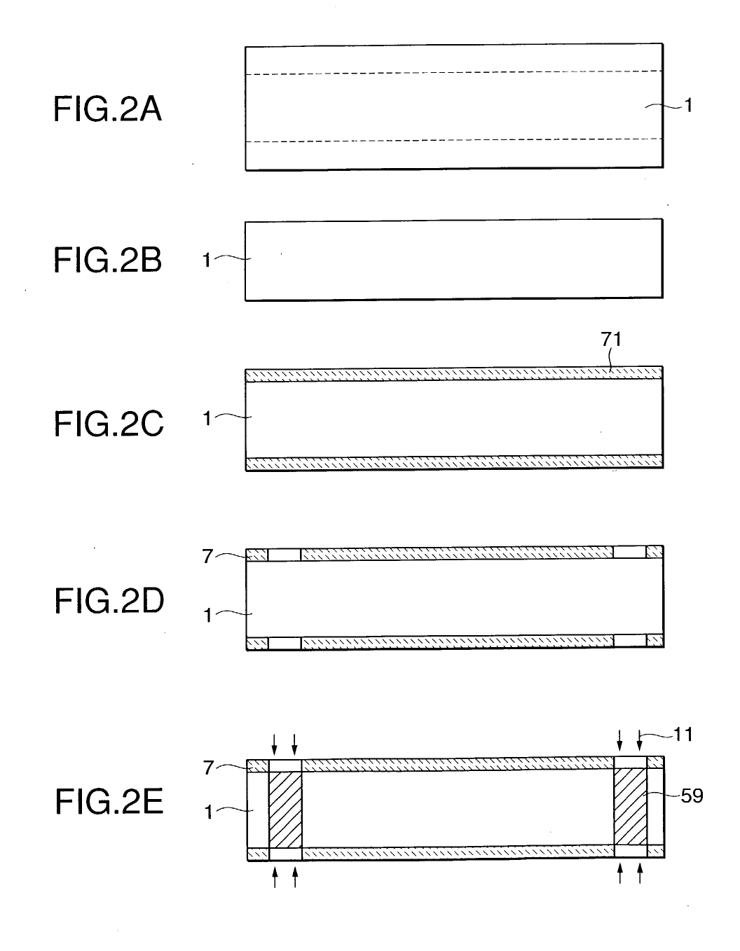

Next, a manufacturing method of the double side connected type semiconductor apparatus in the first embodiment will be described. FIG. 2A to FIG. 5R are schematic sectional views for describing an outline of a manufacturing process for the double side connected type semiconductor apparatus in the first embodiment. First, the semiconductor substrate 1 of Si, GaAs, GaGe or the like is prepared [FIG. 2A]. Both sides of the semiconductor substrate 1 are ground and polished to a level that allows the semiconductor devices to be formed thereon [FIG. 2B]. Oxide films having a predetermined thickness are formed on both sides of the semiconductor substrate polished to a predetermined thickness by a method such as a thermal oxidation method or CVD method, thereby forming first oxide films 71 [FIG. 2C].

First, in order to form the first isolations 5 for electrically separating the conducting units 4, which are formed to penetrate both sides of the semiconductor substrate 1 and electrically enable multistage connection, from the semiconductor devices, a photoresist is applied to both sides of the semiconductor substrate 1 using a known photoresist technique, and both sides are exposed and developed using a mask (not shown), and then the first oxide films 71 in the areas where the first isolations 5 are formed are removed [FIG. 2D]. A first impurity diffusion or ion implantation 11 for forming the isolations is performed in the parts where the first oxide films 71 on both sides of the semiconductor substrate 1 are removed, in accordance with a method such as a thermal diffusion or ion implantation method, thereby forming insulating layers 59 penetrating the semiconductor substrate [FIG. 2E]. To adequately secure isolation through the tops and bottoms of the conducting units 4 of the semiconductor substrate 1, as the diffusion time only by the first impurity diffusion or ion implantation in accordance with a method such as the thermal diffusion or the ion implantation method is not sufficient, additional thermal diffusion is applied at a predetermined temperature for a predetermined period of time until isolation growing areas are connected at the tops and bottoms.

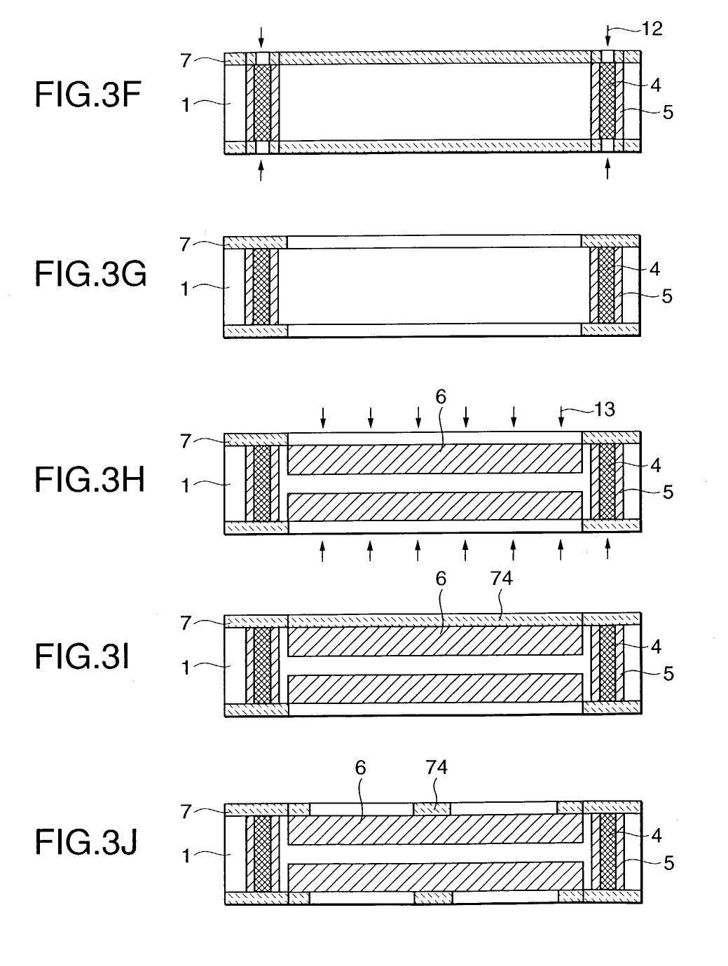

Next, in the same way as shown in FIGS. 2C and 2D, after second oxide films are again formed on both sides of the semiconductor substrate 1, the second oxide films in the parts corresponding to the areas where the conducting units 4 are formed are removed, a second impurity diffusion or ion implantation 12 for producing conductors is performed in the parts where the second oxide films on the semiconductor substrate are removed, so as to form the conducting units 4 as electric conducting parts that penetrate the semiconductor substrate [FIG. 3F]. To adequately secure the electric conduction through the tops and bottoms of the conducting part of the semiconductor substrate, as the diffusion time only by the second impurity diffusion or ion implantation in accordance with a method such as the thermal diffusion or ion implantation method is not sufficient, additional thermal diffusion is applied at a predetermined temperature for a predetermined period of time until the conduction can be secured. For example, if the thickness of the semiconductor substrate 1 is 50 μm, as to the time for Bc13, Po13 and other semiconductor device manufacture impurities to be diffused, the diffusion depth per hour is 2 to 3 μm, which though depends on the surface temperature, when the diffusion temperature is near 1000° C. Therefore, to secure conduction on both sides, nine to thirteen hours are required.

As the formation of the conducting units 4 have been finished in accordance with the processes described above, the semiconductor devices will next be formed on both sides of the semiconductor substrate 1. After third oxide films are formed on both sides of the semiconductor substrate, the photoresist is applied to both sides in accordance with the photoresist technique (not shown). The third oxide films at predetermined positions on both sides of the semiconductor substrate 1 are removed using a mask [FIG. 3G]. A third impurity diffusion or ion implantation 13 for forming the isolations is performed in the parts where the third oxide films 73 are removed, and isolation diffusion is performed to electrically separate the conducting units 4 formed in the prior process from the semiconductor devices that will later be formed, thereby forming second isolations 6 [FIG. 3H].

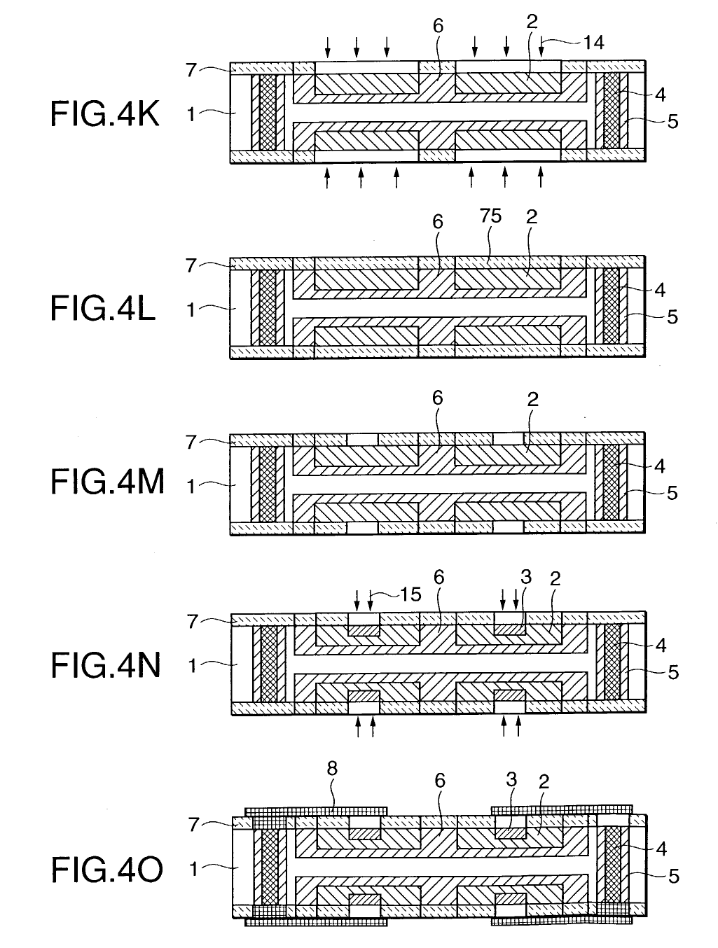

Next, fourth oxide films 74 are formed on both sides of the semiconductor substrate 1 [FIG. 3I]. Then, the photoresist is applied to both sides of the semiconductor substrate 1 in accordance with the photoresist technique so as to form the semiconductor devices in the second isolation areas 6 separated from the conducting units 4 formed earlier, and the fourth oxide films 74 in the areas where the devices are formed on both sides of the semiconductor substrate 1 are removed using a mask [FIG. 3J]. A fourth impurity diffusion or ion implantation 14 for forming the semiconductor devices is performed in the areas where the fourth oxide films 74 are removed, thereby forming first bases 2 for forming the semiconductor devices [FIG. 4K]. Next, fifth oxide films 75 are formed on both sides of the semiconductor substrate 1 [FIG. 4L]. Then, the photoresist is applied to both sides of the semiconductor substrate 1 in accordance with the photoresist technique, and the fifth oxide films 75 at predetermined positions are removed using a mask [FIG. 4M]. A fifth impurity diffusion or ion implantation 15 for forming the semiconductor devices is performed in the parts where the fifth oxide films 75 are removed, thereby forming second bases 3 for forming the semiconductor devices [FIG. 4N]. At this stage, basic transistors are formed. In accordance with the same procedure, diffused resistors necessary for the ICs, diodes and the like are formed (not shown).

Finally, in order to form the ICs, sixth oxide films are formed on both sides of the semiconductor substrate 1, and the photoresist is applied to both sides of the semiconductor substrate 1, and exposure and development are performed using masks fitted to each part, which needs to be contacted, of the transistors, diodes and diffused resistors that form the ICs, and to the conducting units 4, and then the sixth oxide films in the parts needed for connection are removed (not shown). Next, conductor thin films are formed in predetermined areas including the parts where the sixth oxide films are removed by, for example, depositing, spattering or plating an electrode material such as an aluminum-based material or copper-based material. After that, the photoresist is applied to both sides, and both sides are exposed and developed using a mask on which patterns are drawn leaving the conductors for forming the ICs, whereby the formation of the conductors 8 as ICs is finished, leaving the conductor thin films in the parts necessary for connection [FIG. 4O]. In the processes above, the basic double side connected type semiconductor apparatus of a double side diffused type is completed.

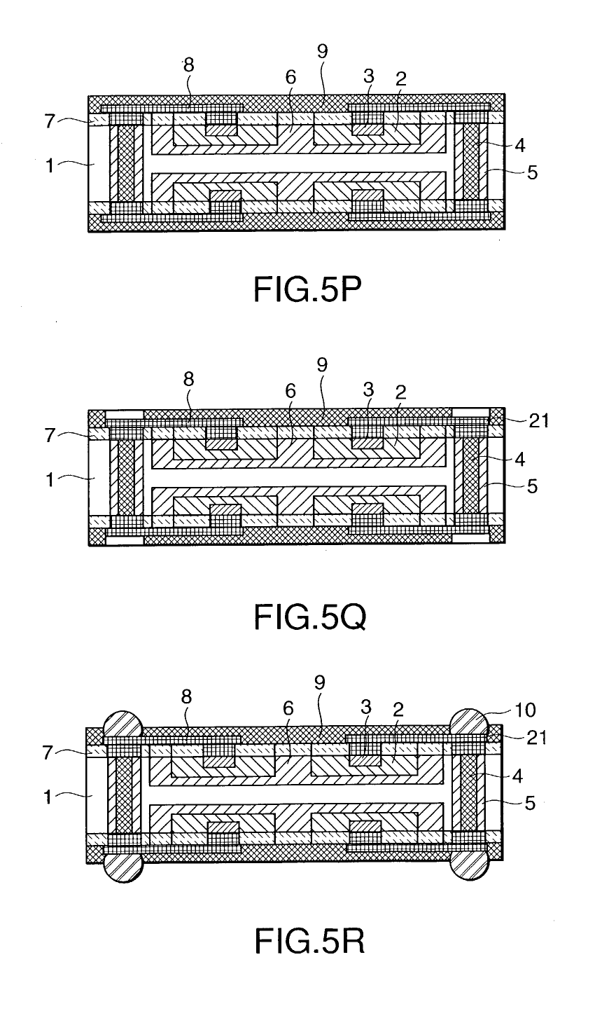

Next, the protection films 9 such as oxide films or polyimide are formed on both sides for protecting the semiconductor devices [FIG. 5P]. The photoresist is applied to both sides of the protection films 9, and both sides are exposed and developed using a mask for removing the protection films 9 only in the parts of external pullout pads of the ICs, and the protection films 9 in the parts of the external pullout pads are removed to form protection film openings, and then the barrier metals 21 are formed in the openings by electroless Ni—Au plating or the like [FIG. 5Q]. Next, the conductive bumps 10 are formed in the parts where the protection films 9 are removed [FIG. 5R]. The bumps 10 may be metal bumps or conductive resins.

Here, the formation of the semiconductor devices and the formation of conducting means are performed separately, however, they can also be performed at the same time.

In this way, the double side connected type semiconductor apparatus of the double side diffused type is completed, which comprises semiconductor devices 2 and 3 electrically insulated under a certain service voltage by the first isolations 5 and second isolation 6, the conducting units 4 for conducting both sides, and the conductors 8 for connecting the above, and has the bumps 10 for multistage connection and the protection films 9 for protecting the semiconductor devices 2 and 3. By laminating the double side connected type semiconductor apparatuses, it is possible to form the multistage laminated type semiconductor apparatus in a second embodiment.

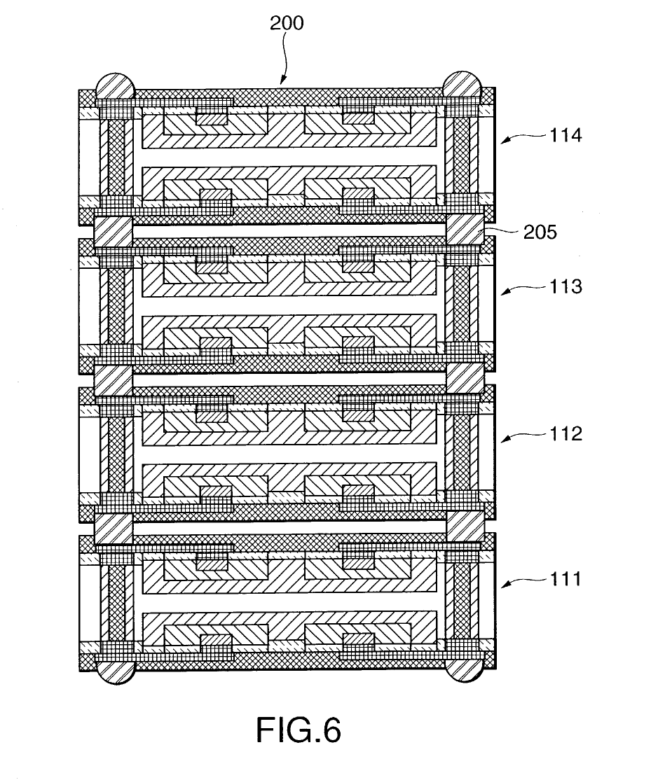

Next, the second embodiment of the present invention will be described. FIG. 6 is a schematic sectional view of the multistage laminated type semiconductor apparatus in the second embodiment of the present invention, and shows an example in which double side connected type semiconductor apparatuses 100 described in the first embodiment are connected to have four stages. In the example, the devices of a first-stage double side connected type semiconductor apparatus 111 which has the bumps 10 formed on both sides, a second-stage double side connected type semiconductor apparatus 112, a third-stage double side connected type semiconductor apparatus 113 and a fourth-stage double side connected type semiconductor apparatus 114 are positioned and laminated, and thus a multistage laminated type semiconductor apparatus 200 constituted of four stages is formed using bump connections 205 formed out of the bumps 10 in accordance with a method such as a reflow method or heat treatment method. The size of this multistage laminated type semiconductor apparatus is exactly the same as a chip size, and the semiconductor devices are formed on both sides by double side diffusion, therefore, this apparatus can accomplish high density mounting twice as much as a multistage laminated type semiconductor apparatus of the prior art.

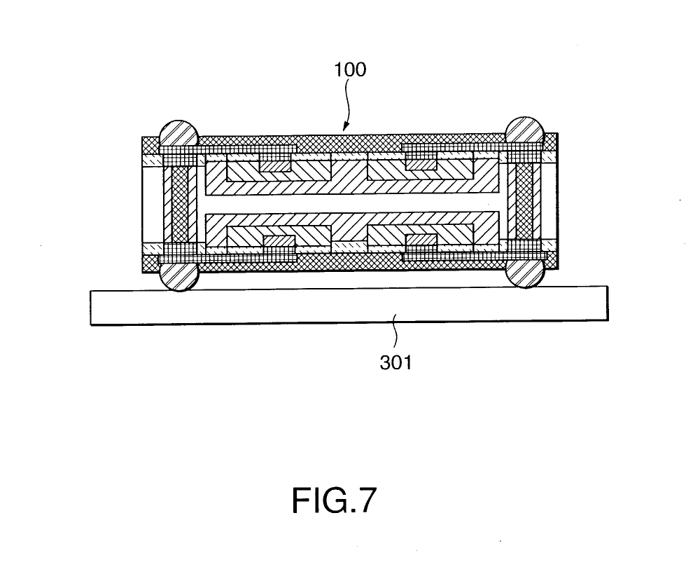

Next, a third embodiment of the present invention will be described. FIG. 7 is a schematic fragmentary sectional view showing a state where the double side connected type semiconductor apparatus in the third embodiment of the present invention is mounted on an electronic component, and shows an example in which a one-stage product of the double side connected type semiconductor apparatus 100 described in the first embodiment is directly mounted on a mother board 301 for forming electronic components in accordance with a method such as the reflow method or heat treatment method. The size of this double side connected type semiconductor apparatus 100 is exactly the same as the chip size, and the semiconductor devices are formed on both sides by double side diffusion, therefore, this apparatus can accomplish high density mounting twice as much as that of the prior art.

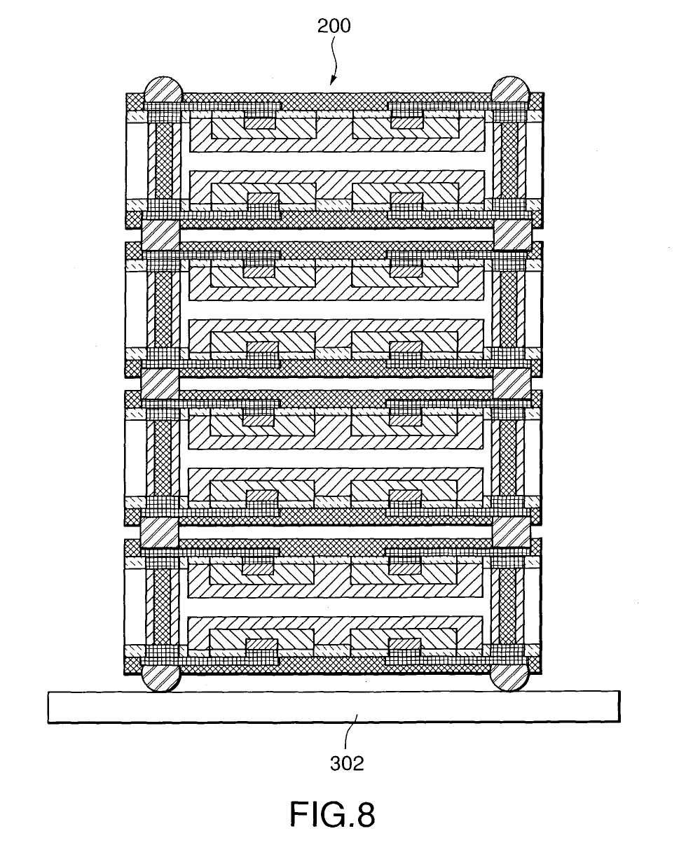

Next, a fourth embodiment of the present invention will be described. FIG. 8 is a schematic fragmentary sectional view showing a state where the multistage laminated type semiconductor apparatus in the fourth embodiment of the present invention is mounted on an electronic component, and shows an example in which the multistage laminated type semiconductor apparatus constituted of four stages by laminating the double side connected type semiconductor apparatuses 100 described in the second embodiment is directly mounted on a mother board 302 in accordance with a method such as the reflow method or heat treatment method. The size of this multistage laminated type semiconductor apparatus is exactly the same as the chip size, and the semiconductor devices are formed on both sides by double side diffusion, therefore, this apparatus can accomplish high density mounting twice as much as the multistage laminated type semiconductor apparatus of the prior art.

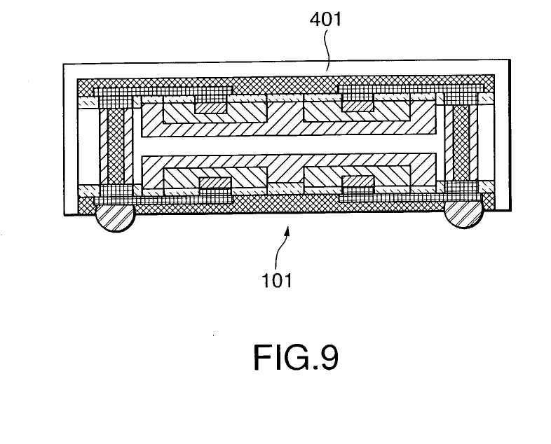

Next, a fifth embodiment of the present invention will be described. FIG. 9 is a schematic fragmentary sectional view showing a state where the double side connected type semiconductor apparatus in the fifth embodiment of the present invention is resin-encapsulated. The bumps are removed on one side of the one-stage product of the double side connected type semiconductor apparatus 100 described in the first embodiment, and the one side is resin-encapsulated by an encapsulation resin 401, thus providing a double side connected type semiconductor apparatus 101 having a constitution in which reliability is enhanced by resin encapsulation. The resin encapsulation may be applied without removing the bumps on one side. The semiconductor devices are formed on both sides by double side diffusion, therefore, this apparatus can accomplish high density mounting twice as much as that of the prior art.

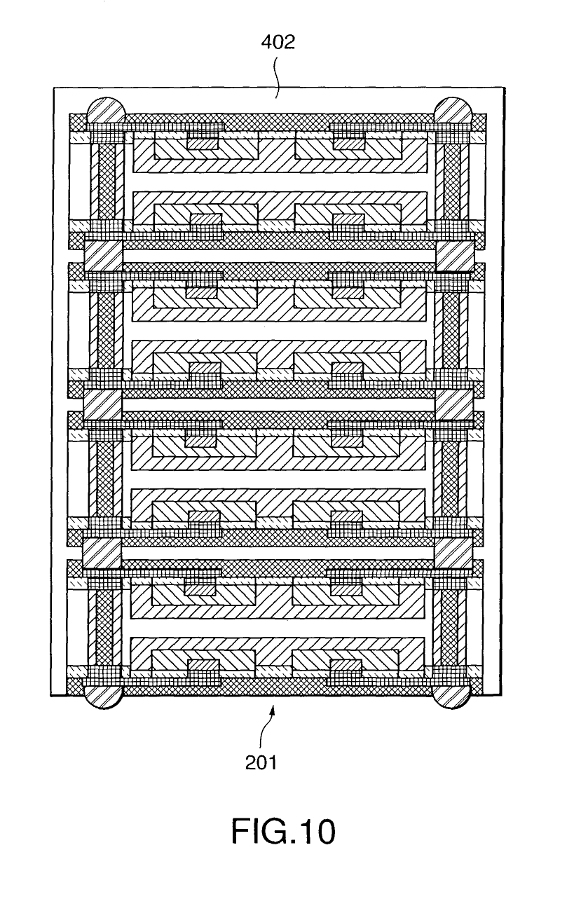

Next, a sixth embodiment of the present invention will be described. FIG. 10 is a schematic fragmentary sectional view showing a state where the multistage laminated type semiconductor apparatus in the sixth embodiment of the present invention is resin-encapsulated, and the multistage laminated type semiconductor apparatus 200 described in the second embodiment is resin encapsulated by an encapsulation resin 402, thus providing a multistage laminated type semiconductor apparatus 201 having a constitution in which reliability is enhanced by resin encapsulation. The resin encapsulation may be applied after removing the bumps on the side to be encapsulated. The semiconductor devices are formed on both sides by double side diffusion, therefore, this apparatus can accomplish high density mounting eight times as much as the single-stage semiconductor apparatus of the prior art.

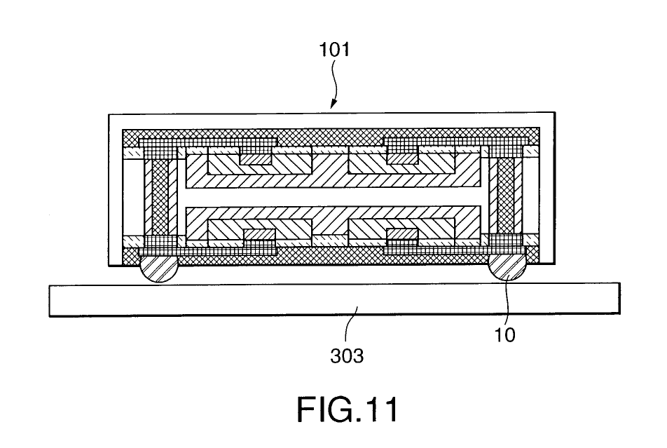

Next, a seventh embodiment of the present invention will be described. FIG. 11 is a schematic fragmentary sectional view showing a state where the resin-encapsulated double side connected type semiconductor apparatus in the seventh embodiment of the present invention is mounted on an electronic component, and shows an example in which the resin-encapsulated double side connected type semiconductor apparatus 101 described in the fifth embodiment is directly mounted on a mother board 303 for forming electronic components via the bumps 10 in accordance with a method such as the reflow method or heat treatment method. In this double side connected type semiconductor apparatus 101, the semiconductor devices are formed on both sides by double side diffusion, therefore, it is possible to accomplish high density mounting twice as much as that of the prior art.

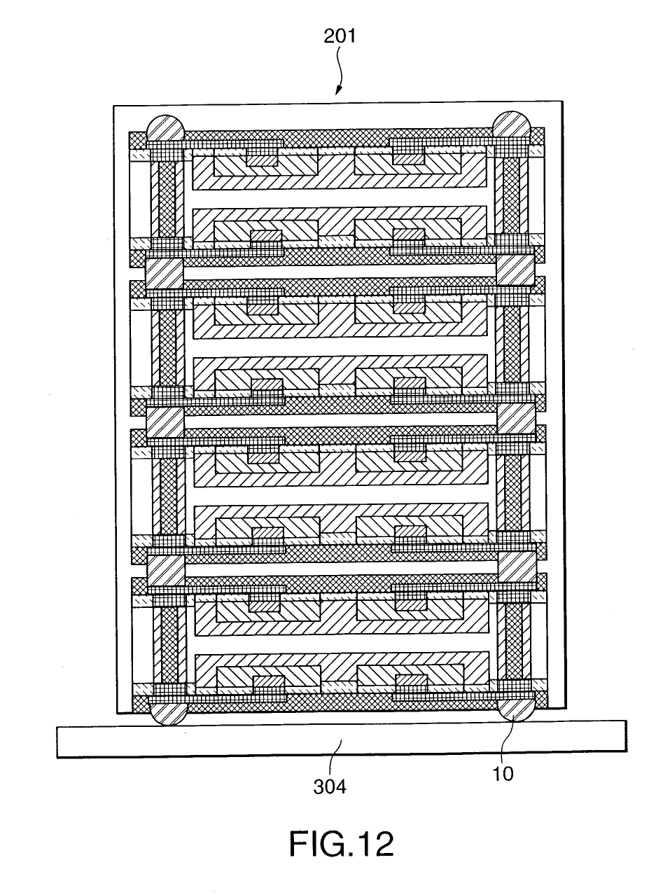

Next, an eighth embodiment of the present invention will be described. FIG. 12 is a schematic fragmentary sectional view showing a state where the resin-encapsulated multistage laminated type semiconductor apparatus in the eighth embodiment of the present invention is mounted on an electronic component, and shows an example in which the multistage laminated type semiconductor apparatus 201 constituted of four stages by laminating and resinen-capsulating the double side connected type semiconductor apparatuses described in the sixth embodiment is directly mounted on a mother board 304 for forming electronic components in accordance with a method such as the reflow method or heat treatment method. In this multistage laminated type semiconductor apparatus 201, the semiconductor devices are formed on both sides by double side diffusion, therefore, it is possible to accomplish high density mounting eight times as much as the single-stage semiconductor apparatus of the prior art.

As described above, the advantage of the double side connected type semiconductor apparatus and the multistage laminated type semiconductor apparatus constituted by laminating the double side connected type semiconductor apparatuses according to the present invention is that they can be formed using the conventional semiconductor diffusion process as it is, since vertical conduction is kept at pad positions of the semiconductor devices. Therefore, when the semiconductor devices are formed or the conducting means are formed, simultaneous diffusion or separate diffusion may be possible, and only the order of processes may be changed. Consequently, when a conducting element for vertical conduction is formed, it is not necessary to have protection means for protecting the semiconductor devices already completed and a process for removing them, and different kinds of processes would not be mixed, thereby providing the advantage that the total number of processes does not increase. In addition, since the semiconductor substrate itself is used for the vertical conducting means, quality does not deteriorate due to the difference in thermal expansion and thermal conduction.

In terms of high density, the foundation is not packaging but bare chip assembly, so that the semiconductor apparatus equivalent to the chip size can be achieved, and the semiconductor devices are formed on both sides of the semiconductor substrate, thereby providing the advantage that the degree of location is dramatically improved twice as much as that of the prior art even in the case of a single stage.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A double side connected type semiconductor apparatus comprising pads for external connection on both sides, semiconductor devices formed on both sides of a semiconductor substrate, and conductor portions which perform electrical connection between the pads and between the pads and the semiconductor devices, wherein
the semiconductor devices are formed on both the sides of the semiconductor substrate in accordance with a selective impurity diffusing method;
the conductor portions are formed in such a manner that impurities are diffused only in required parts on both the sides of the semiconductor substrate in accordance with the selective impurity diffusing method, so that a resistivity of the diffused part of the semiconductor substrate lowers, which enables electric conduction; and
the conductor portions are electrically insulated from the semiconductor devices by isolations.

2. The double side connected type semiconductor apparatus according to claim 1, wherein said conductor portions and said semiconductor devices are further electrically connected by junctions or conductors formed according to a impurity diffusing method applied to conductor metal wiring or the semiconductor substrate.

3. The double side connected type semiconductor apparatus according to claim 1, wherein said semiconductor devices are disposed on both sides of said semiconductor substrate at a position where identical patterns are opposite to each other.

4. The double side connected type semiconductor apparatus according to claim 1, wherein said semiconductor devices are disposed on both sides of said semiconductor substrate at a position where identical patterns are opposite to each other in a state turned 180 degrees.

5. The double side connected type semiconductor apparatus according to claim 1, wherein barrier metals are formed on said pads on both sides.

6. The double side connected type semiconductor apparatus according to claim 1, wherein barrier metals are formed on said pads on one side.

7. The double side connected type semiconductor apparatus according to claim 1, wherein at least one of metal bumps or conductive resin bumps are formed on said pads on both sides.

8. The double side connected type semiconductor apparatus according to claim 1, wherein at least either metal bumps or conductive resin bumps are formed on said pads on one side.

9. The double side connected type semiconductor apparatus according to any of claim 5 to claim 8, wherein the entire is resin-encapsulated except for the mounting bumps.
